(19) United States
(12) Patent Application Publication
(10) Pub. No.: US 2025/0234657 A1
(43) Pub. Date: Jul. 17, 2025

(54) SYSTEM AND METHODS FOR MANUFACTURING A CRISSCROSS MATRIX OF SOLAR CELLS

(71) Applicant: SOLARWAT LTD., Even Yehuda (IL)

(72) Inventors: Boris VATELMACHER, Even Yehuda (IL); Aleksei KUKIN, Rishon LeTsiyon (IL)

(73) Assignee: SOLARWAT LTD., Even Yehuda (IL)

(21) Appl. No.: 18/730,779

(22) PCT Filed: Feb. 1, 2023
(86) PCT No.: PCT/IL2023/050112

§ 371 Date: Jul. 21, 2024

Related U.S. Application Data
(60) Provisional application No. 63/305,307, filed on Feb. 1, 2022.

(51) Int. Cl. H10F 19/90

(52) U.S. Cl. CPC H10F 19/904

(57) ABSTRACT

A method for manufacturing a PV solar cells matrix array (SCMA) of m×n PV solar cells that are interconnected both in parallel and and in series. The solar cells are interconnected by a flexible conductor foil, row by row, wherein each pair of adjacent rows of solar cells are conductively interconnected by a single flexible conductor foil. Hence, the SCMA of m×n PV solar cells are inter connected by n-\ parallel and series connection conductors, that are preferably solder ready by either high temperature solder or by low temperature solder.

### FIELD OF THE INVENTION

The present invention relates to systems and methods for manufacturing solar array modules for generating electric-power and more particularly, to systems and methods having PV solar cells interconnected in a crisscross matrix array configuration.

### BACKGROUND OF THE INVENTION

The manufacturing system and method of the present disclosure relates to manufacturing lines of production and manufacturing processes of solar panels having an array of solar cells that are electrically interconnected both in serial and in parallel.

The present disclosure relates to manufacturing lines and processes of photo-voltaic (PV) solar panels. A conventional solar panel manufacturing line utilizing several conventional electric busbars connection technology by using several conductors with round or rectangular cross section, wherein the soldering and lamination processes are separated. A mostly automatic production line that utilizes common process for producing PV panels with regular solar cells, one can refer to a video in the following link: https://www.solarmakingmachine.com.

The mainstream technological process for solar panel manufacturing involves placement the several quantities of Busbars or Smart Wires (SW) on cell and afterword soldering the Busbars or SW into a metallization layer of PV solar cells including cell to cell serial interconnection and/or matrix interconnection. In most PV modules, the cells are placed with gaps between all neighboring cells, which require increasing the panel length and/or width.

Generally, the busbars placement and soldering are the most complicated and lengthy part of the entire panel assembly process, and requires additional equipment which makes the automatic manufacturing line substantially more complex and expensive.

Reference is made to FIG. 1a (prior art) that illustrates an example conventional manufacturing technology receptor conveyor 40 that is configured to convey regular solar cells 20. An arm catcher (typically, a “robotic catcher”) is configured to place regular solar cells 20, one by one, on a regular receptor conveyor belt 42, wherein regular solar cells 20 are spaced apart by a predesigned gap.

Typically, another robotic catcher (not shown) is configured to picked up the regular solar cells 20, from the receptor conveyor belt 42 and place them on a common stringer conveyer 50 having a common wide stringer conveyer belt 52 configured for a “Busbars Lay-Up” in which step busbars 25 are laid-up on a column of regular solar cells 20 in order to produce a single string having a predesign number of regular solar cells 20 that are electrically connected in series. An example common stringer conveyer 50 is shown in FIG. 1b (prior art). The regular solar cells 20 are placed on common stringer conveyer belt 52 aligned to form a string of regular solar cells 20 spaces apart by predesigned gaps. In the non-limiting example shown in FIG. 1b, the array of regular solar cells 20 includes a string (column) of regular solar cells 20, and by way of a non-limiting example the description refers to an array of 6 such strings (columns), each having 10 regular solar cells 20.

Common stringer conveyer 50 further includes means for placing common wiring busbars 25 along the string of regular solar cells 20 (for example, with no limitations, 10 regular solar cells 20 a number of busbars 25 (typically from 3 to 12 and more). Common stringer conveyer 50 conveys the column of regular solar cells 20 and the busbars 25 through a soldering oven 54, yielding a single string of regular solar cells 20 that are electrically connected in series.

PCT/IL2021/050943 discloses systems and methods for manufacturing solar array modules configured to generate electric-power and more particularly, to systems having PV solar sub cells interconnected in a crisscross matrix array configuration, wherein the solar cells are cut into sub cells, and wherein the production line includes placingObusbars or groups of Smart Wire (SW) conductors on each of the n columns of the solar sub-cells to thereby electrically connect the columns of the solar sub-cells in series. PCT/IL2021/050943 further discloses placing and soldering short parallel jumpers between all pairs of neighboring the solar sub-cells in each of the m rows of the solar sub-cells, and thereby electrically connect the columns of the solar sub-cells in parallel.

There is therefore a need, and it would be advantages to provide production lines for manufacturing panels having a crisscross matrix array of solar, wherein such production lines will provide reduced complexity of the process and the time now required to execute all of the manufacturing steps, and consequently, substantially decrease the process efficiency and reduce the manufacturing time and the automatic line equipment cost. It would be farther advantages to eliminate the use of busbars in the production lines of solar panels in terms of costs and production time.

### SUMMARY OF THE INVENTION

Unless otherwise defined herein, all technical and/or scientific terms used herein have the same meaning as commonly understood by one of ordinary skill in the art to which the invention pertains. Although methods and materials similar or equivalent to those described herein may be used in the practice or testing of embodiments of the invention, example methods and/or materials are described below. In case of conflict, the patent specification, including definitions, will control. In addition, the materials, methods, and examples are illustrative only and are not intended to be necessarily limiting.

It should be noted that the terms “electrical” or “electrically wired”, as used herein refer to the electrical configuration of the matrix, regardless of the physical configuration of the solar cells in the solar panel. Similarly, it should be further noted that the term “physical” as used herein refers to the physical placement of solar cells in the module/panel, regardless of the electrical inter-wiring of the solar cells.

It should be appreciated that the present disclosure eliminates the use of busbars which substantially reduces the manufacturing cost and time of the solar panel, as well as increase the solar panel efficiency, since the busbars block the incoming light.

The PV solar cells of the array of cells are stuck up such that there is no gap formed between adjacent cells. Therefore, the overall area of the taken by the array of cells is reduced, and thereby increase the efficiency of the panel of PV solar cells.

It should be further noted that the terms “electrical” or “electrically wired”, as used herein refer to the electrical configuration of the matrix, regardless of the physical configuration of the solar cells in the solar panel. Similarly, it should be further noted that the term “physical” as used herein refers to the physical placement of solar cells in the module/panel, regardless of the electrical inter-wiring of the solar cells.

According to the teachings of the present invention there is provided a method for manufacturing a PV solar cells matrix array (SCMA) of generally quadrangular solar cells, having a rear side, a front side, an upper side and a lower side. It should be noted that orientation related descriptions such as “bottom”, “up”, “upper”, “down”, “lower”, “top” and the like, assumes that the solar panel is lying on a horizontally plat surface.

Each solar cell is covered by an upper conductive contact grid having a first electric pole (FEP), and a lower side that is covered by a lower conductive contact grid having a having a second electric pole (SEP) being opposite to the FEP. Typically, with no limitations, the upper conductive contact grid is a plus (+), and the lower conductive contact grid is a minus (+).

Each row of the SCMA includes m solar cells, and each column of the array of solar cells includes n solar cells, all of which are electrically interconnect both in series and in parallel.

The method including the steps of:
a) providing n−1 flexible, parallel-and-serial connection conductors, each including an upper horizontal surface, a generally vertical surface, and a bottom horizontal surface,
   wherein the flexible, parallel-and-serial connection conductors are single layer parallel-and-serial connection conductors;
   wherein the vertical surface of each of the single layer parallel-and-serial connection conductor is configured to be attached to either the front side, the rear side or both the front and rear sides, of each of the m placed solar cells;
   wherein the upper horizontal surface of each of the single layer parallel-and-serial connection conductors, except for the first row, is configured to be conductively attached to the respective upper conductive contact grid of the previous solar cell; and
   wherein the bottom horizontal surface of each the single layer parallel-and-serial connection conductors, except for the last row, is configured to be conductively attached to the respective lower conductive contact grid of the next solar cell,
b) providing m×n PV solar cells;
c) assembling the array of m×n PV solar cells wherein, proceeding with either:
   i) placing a stuck row of m of the solar cells onto a flat surface,
      placing the vertical surface of a single layer parallel-and-serial connection conductor adjacent to the front side of the placed stuck row of m of solar cells, and
      wherein the upper horizontal surface of the placed single layer parallel-and-serial connection conductor is placed adjacent to the upper conductive contact grid of the the placed stuck row of m of the solar cells;
   ii) placing the next stuck row of m of the solar cells onto a flat surface, wherein the rear end of the lower conductive contact grid of the placed stuck row of m of the solar cells is placed over and adjacent to bottom horizontal surface;
   iii) placing the vertical surface of the first single layer parallel-and-serial connection conductor adjacent to the front side of the placed stuck row of m of the solar cells;
   iv) repeat steps vi-vii until reaching the last stuck row of m of the solar cells;
   v) placing the nth stuck row of m of the solar cells onto a flat surface, wherein the rear end of the lower conductive contact grid of the last placed stuck row of m of the solar cells is placed over and adjacent to bottom horizontal surface,
or with:
   i) providing a first single layer parallel-and-serial connection conductor;
   ii) placing a stuck row of m of the solar cells onto a flat surface,
      wherein the vertical surface of the provided single layer parallel-and-serial connection conductor is placed adjacent to the front side of the placed stuck row of m of the placed solar cells, and
      wherein the lower horizontal surface of the last placed single layer parallel-and-serial connection conductor is placed adjacent the lower conductive contact grid of the last placed stuck row of m of the solar cells, except for the last row;
   iii) placing the next stuck row of m of the solar cells onto a flat surface, wherein the rear end of the upper conductive contact grid of the placed stuck row of m of the solar cells is placed below and adjacent to upper horizontal surface;
   iv) placing the vertical surface of the first single layer parallel-and-serial connection conductor adjacent to the front side of the placed stuck row of m of the solar cells;
   v) repeat steps vi-vii until reaching the last stuck row of m of the solar cells;
      placing the nth stuck row of m of the solar cells onto a flat surface, wherein the front end of the upper conductive contact grid of the placed stuck row of m of the solar cells is placed below and adjacent to upper horizontal surface,
d) soldering the assembled array of m×n PV solar cells.

The parallel-and-serial connection conductor is made of conductive material, wherein the conductive material may be a metal such as cupper or silver.

The parallel-and-serial connection conductor may be a multi-layer, parallel and serial conductor foil, wherein the multi-layer, parallel and serial conductor foil includes:
a. an upper non-conductive polymer foil with an adhesive lower side;
b. a metal foil that is solder ready coated; and
c. a lower non-conductive polymer foil with an adhesive upper side, wherein the three layers are glued together in a staggering manner such that parts of the adhesive lower side and the adhesive upper side are left untouched.

Optionally, either the upper non-conductive polymer foil, the lower non-conductive polymer foil, or both are transparent.

Optionally, the soldering of the assembled array of m×n PV solar cell is performed using low temperature soldering, or by using high temperature soldering, or a combination of both high temperature soldering and low temperature soldering.

Optionally, the flat surface is a receptor conveyor.

Optionally, the upper conductive contact grid further includes a conductive pad, and wherein the respective parallel and serial conductor is configured to be conductively attached to the plus conductive pad.

Optionally, the lower conductive contact grid further includes a conductive pad, and wherein the respective parallel and serial conductor is configured to be conductively attached to the minus conductive pad.

Preferably, a non-conductive region j is kept between the front end of the lower conductive contact grid and the front side of the body of the respective PV solar cell.

Preferably, a non-conductive region k is kept between the rear end of upper lower conductive contact grid and the rear side of the body of the respective PV solar cell.

Optionally, the PV solar cells are regular solar cells.

Optionally the PV solar cells are cut from regular solar cells.

Preferably the upper conductive contact grid is configured to face the incoming light.

### BRIEF DESCRIPTION OF THE DRAWINGS

The present invention will become fully understood from the detailed description given herein below and the accompanying drawings, which are given by way of illustration and example only, and thus not limiting in any way, wherein:

FIG. 1a (prior art) is a schematic illustration of illustrates an example conventional manufacturing technology receptor conveyor that is configured to convey regular solar cells.

FIG. 1b (prior art) is a schematic illustration of illustrates an example conventional manufacturing technology receptor conveyor that is configured to convey regular solar cells.

FIG. 2 illustrates an example side cross section view of a PV solar cell, according to one embodiment of the present invention.

FIG. 3a illustrates an example, side elevated perspective view of a parallel and series connection conductor, according to some embodiments of the present invention.

FIG. 3b illustrates another example, side elevated perspective view of a portion of a parallel and series connection conductor, having an example more rounded profile, according to some embodiments of the present invention.

FIG. 4 is a top view of the first two rows of two strings of a PV solar of the m strings and n rows of the array of PV solar cell, according to embodiments of the present invention.

FIG. 5, illustrates a side cross section view AA′ of a string of PV solar cells that are electrically connected in series, according to some embodiments of the present invention.

FIG. 6 an example side cross section view of PV solar cell, according to some other embodiments of the present invention.

FIG. 7a illustrates an example multi-layer, parallel-and-serial connection conductor foils, according to some embodiments of the present invention.

FIG. 7b illustrates a cross section view of the multi-layer parallel-and-serial connection conductor foils shown in FIG. 7a.

FIG. 8 illustrates a top view of the first rows of two strings of PV solar cells of the m strings and n rows of the array of PV solar cell, wherein the two strings are also electrically connected in series, according to embodiments of the present invention.

FIG. 9, according to embodiments of the present invention, is a side cross section view CC′ of the first two rows of PV solar cells, according to embodiments of the present invention.

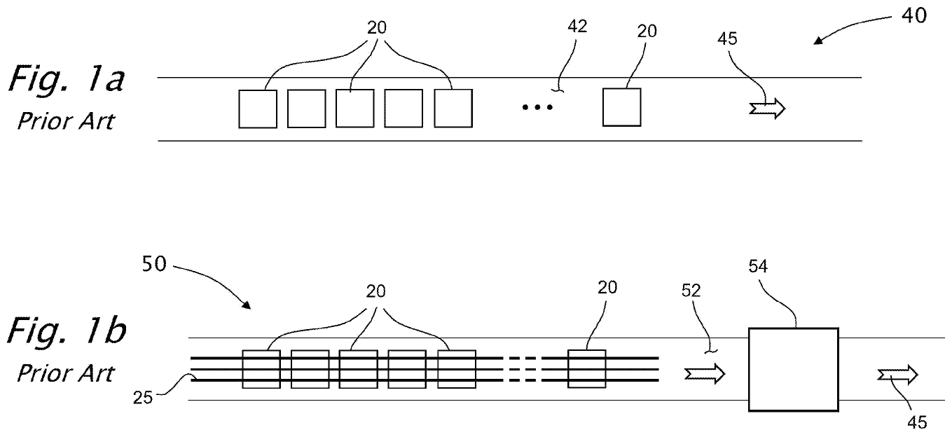

### DETAILED DESCRIPTION OF THE INVENTION

The present invention now will be described more fully hereinafter with reference to the accompanying drawings, in which preferred embodiments of the invention are shown.

The present disclosure will now be described more fully hereinafter with reference to the accompanying drawings, in which preferred embodiments of the disclosure are shown. This disclosure may, however, be embodied in many different forms and should not be construed as limited to the embodiments set forth herein; rather, these embodiments are provided, so that this disclosure will be thorough and complete, and will fully convey the scope of the invention to those skilled in the art.

An embodiment is an example or implementation of the disclosures. The various appearances of “one embodiment,” “an embodiment” or “some embodiments” do not necessarily all refer to the same embodiment. Although various features of the disclosure may be described in the context of a single embodiment, the features may also be provided separately or in any suitable combination. Conversely, although the disclosure may be described herein in the context of separate embodiments for clarity, the disclosure may also be implemented in a single embodiment.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the disclosures. It is understood that the phraseology and terminology employed herein are not to be construed as limiting and are for descriptive purpose only.

Meanings of technical and scientific terms used herein are to be commonly understood as to which the disclosure belongs, unless otherwise defined. The present disclosure can be implemented in the testing or practice with methods and materials equivalent or similar to those described herein.

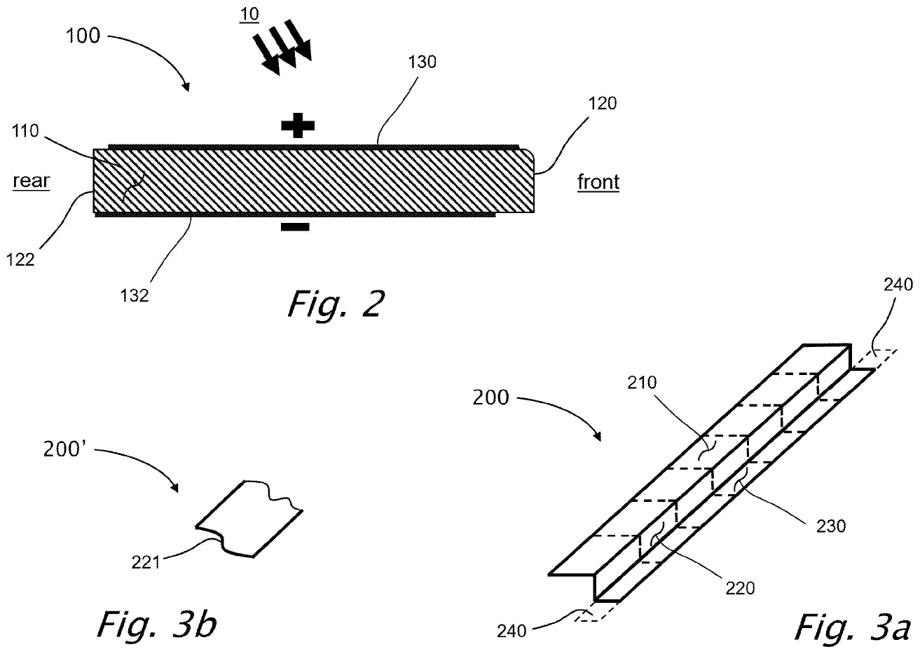

Reference is made back to the drawings. FIG. 2 illustrates an example side cross section view of PV solar cell 100 according to one embodiment of the present invention, wherein PV solar cell 100 is typically, with no limitations, made of silicon. PV solar cell 100 includes a common body 110 having a front side 120 and a rear side 122, wherein typically, with no limitations, the upper side is the plus, positive (+) side, that is shown facing the incoming light 10, and the lower side is the negative (−) side. However, depending on the solar cell technology, either the upper side of PV solar cell 100 or the lower side or both of these sides may be exposed incoming light 10. Typically, with no limitations, the upper side of each PV solar cell 100 is covered by an upper conductive contact grid 130 that includes a network of thin conductors 118 that are configured to collect the electric current generated by the PV solar cell 100. Typically, the lower sides of each PV solar cell 100 is covered by a lower conductive contact grid 132. However, at least the front side of the lower conductive contact grid (132) does not reach the rear end 120 of PV solar cell 100. Preferably, at least the front side of the upper conductive contact grid (130) does not reach the front end 122 of PV solar cell 100.

A solar panel of the present invention includes n rows of PV solar cell 100, wherein each row includes m PV solar cells 100. In the production line, all PV solar cells 100 are placed in stuck (closely adjacent to one another) on a flat surface, substantially without any space between them. The cell connection in series and parallel is provided using one tin-coated (solder or low temperature solder) conductor. In a first production step, m PV solar cells 100, that are typically designated to be the first row of the matrix array of PV solar cells 100 that is being produced, are placed side-by-side in stuck, that is, adjacent to each other. Optionally, the flat surface is the upper surface of a receptor conveyor such, with no limitations, as a conveyor belt.

A solar panel of the present invention further includes at least n−1 parallel and series connection conductors 200, one of which is illustrated by way of example in FIG. 3a. A single parallel and series connection conductor 200 has a width that facilitates connecting in parallel at least m strings, and two PV solar cells 100 of each string in series. n−1 parallel and series connection conductors 200 connect all of the n rows of the array of PV solar cells 100 in series. Parallel and series connection conductor 200 is made of conductive material such copper. Each parallel and series connection conductor 200 includes an upper surface 210 configured to be conductively placed over the side of all of the PV solar cells 100 in stuck at the production line, includes a to be placed adjacent to a vertical front of the stuck at the production line. Optionally, vertical surface 220 is generally vertically as shown in FIG. 3b, showing a portion of a parallel and series connection conductor 200′ where, by way of example, vertical surface 221 is shown rounded. Each parallel and series connection conductor 200 further includes a bottom horizontal surface 230 configured to receive the next stuck of m PV solar cells 100 of the n rows series connection. Typically, each parallel and series connection conductor 200 is a tin-coated conductor, either by high temperature solder or by low temperature solder. Parallel and series connection conductor 200 may further include at least one conductive extension, for example of one or more horizontal extensions 240, to facilitate a bypass diode parallel connection.

It should be appreciated that the order in which the rows of n PV solar cells 100 are placed adjacent to each other are given by way of example only. In the next step another n PV solar cells 100 are placed in stuck over the respective lower surface 230 of the parallel and series connection conductor 200, and adjacent to a vertical surface 220 parallel and series connection conductor 200 of the placed parallel and series connection conductor 200. This process proceeds until all of the m rows of PV solar cell 100 are in place. Parallel and series connection conductor 200 are conductively bonded on the respective PV solar cells 100 during the manufacturing process of the PV solar cells array.

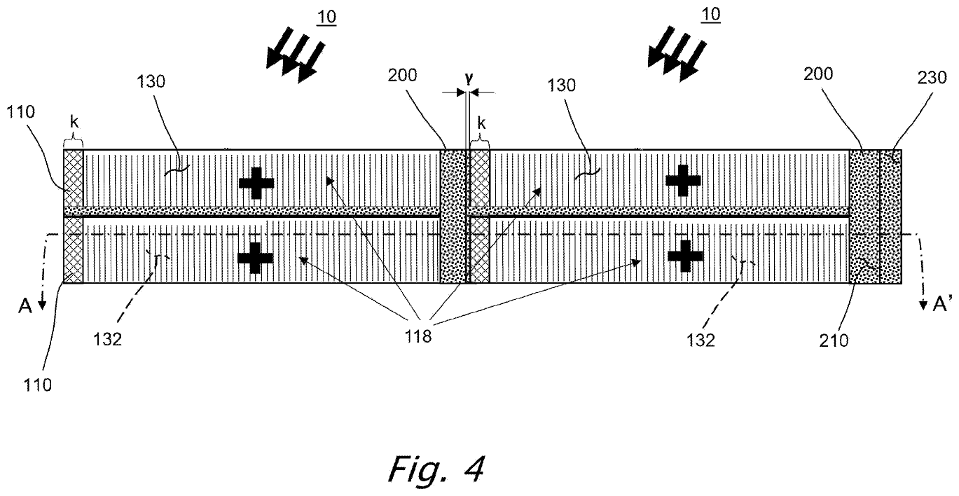

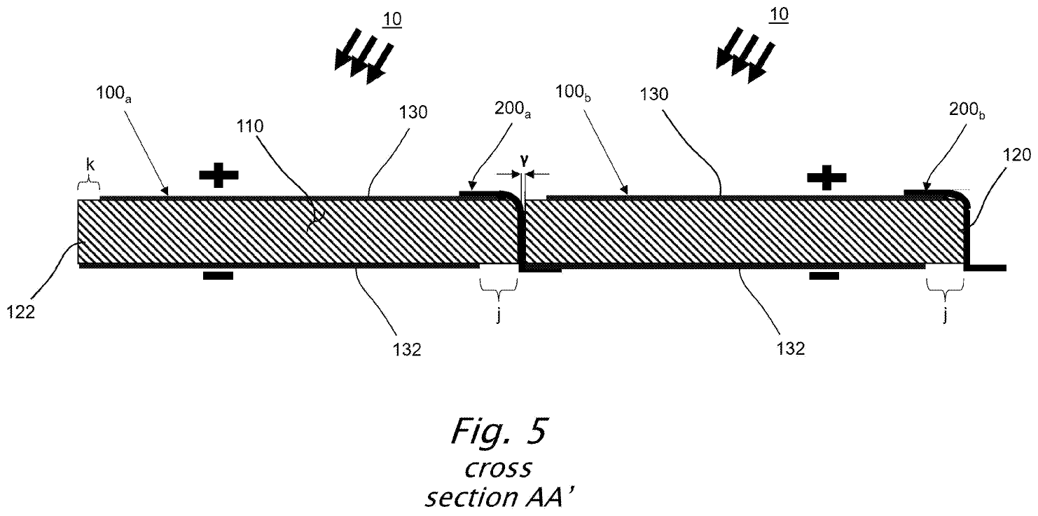

Reference is also now made to FIG. 4, which is a top view of the first two rows of two strings of PV solar cells 100 of the m strings and n rows of the array of m×n PV solar cell 100 that are electrically connected in series. Reference is also now made to FIG. 5, which is a side cross section view AA′ of two PV solar cells 100 that are electrically connected in series, according to some embodiments of the present invention. The electrically positive side being the plus, upper conductive contact grid 130 of each of the PV solar cells 100 is connected in series with the electrically negative, side, lower conductive contact grid 132 of the next solar cell 100 of the same string of solar cells. The gap between the two connected cells is y=0. Parallel and series connection conductor 200a is shown connecting the positive side of the plus-conductor, upper conductive contact grid 130 of the first PV solar cells 100a with the negative side minus-conductor, lower conductive contact grid 132 of the next solar cell 100b of the same string of PV solar cells 100.

The PV solar cells 100 that are connected in series constitute a string of PV solar cells 100. However, the one parallel and series connection conductor 200 connects in parallel the neighboring PV solar cells 100 as well. The PV solar cells 100 that are connected in parallel create a row of PV solar cells 100. The length of parallel and series connection conductor 200 is equal to the width of all strings together, i.e. one parallel and series connection conductor 200 connects all neighboring PV solar cells 100 of the same row in parallel and connects the PV solar cells 100 of adjacent rows in series that forms a matrix (crisscross) network connection of entire array of PV solar cells 100. The connected array of m×n PV solar cells 100 passes through a soldering step (via a soldering oven or a process of soldering during the lamination process) to activate the soldering all required connections. To avoid erroneous connection of the positive layer of adjacent PV solar cells 100 during the soldering process, the positive conductive layer being the upper conductive contact grid 130 of each PV solar cell 100 has non-conductive region k (see FIG. 5) at the rear side 122 of the PV solar cells 100. Similarly, the negative conductive lower conductive contact grid 132 of each PV solar cell 100 has non-conductive region j (see FIG. 5) at the front side 120 of the PV solar cells 100.

The PV solar cells 100 interconnection in series and in parallel is provided, for example, by using one tin-coated conductor foil, either by high temperature solder or by low temperature solder, for example indium or bismuth base solders. In the case of low temperature solders, polymer films can be integrated in the tin-coated parallel and series connection conductor foil 200, on both sides, such that they cover surface of the tin-coated conductor foil 200, and leave only space for connection to the respective solar cells 100.

The upper side 210 of the tin-coated parallel and series connection conductor foil 200 is soldered directly, by upper side 210 and lower side 230, respectively, to upper conductive contact grid 130 and lower conductive contact grid 132 of solar cells 100 to thin wires 118 spread over the upper conductive contact grid, plus-conductor, upper conductive contact grid (130) and lower conductive contact grid (132) areas of solar cell 100 that create electrical connection between m cells of neighboring rows and strings of cells as shown on FIG. 4 that allows the cells current of the respective PV solar cell 100 flows through all strings of cells.

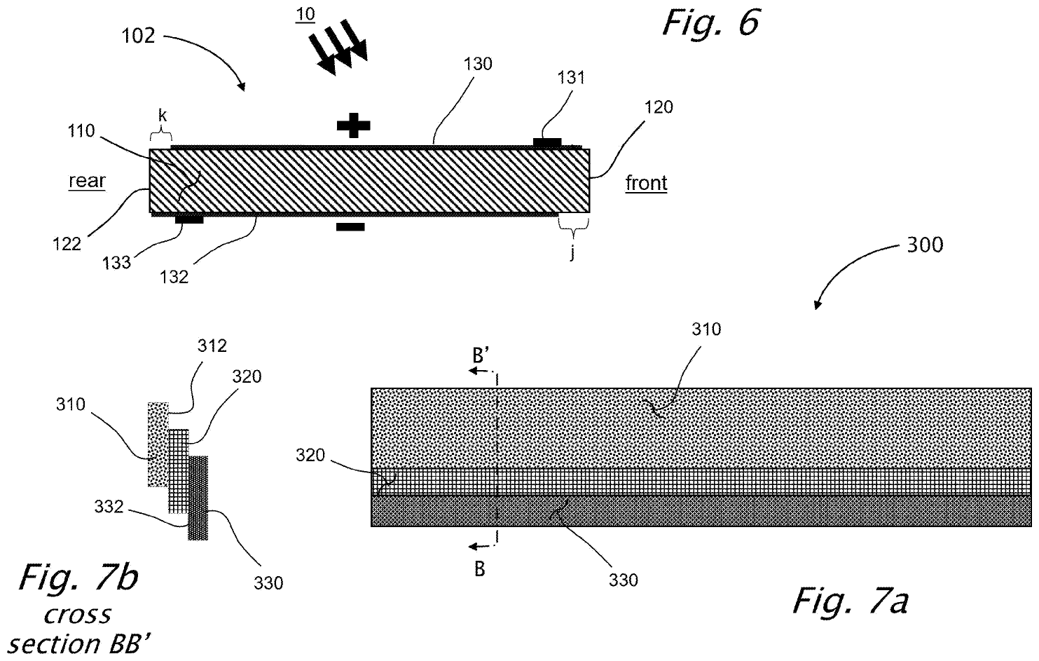

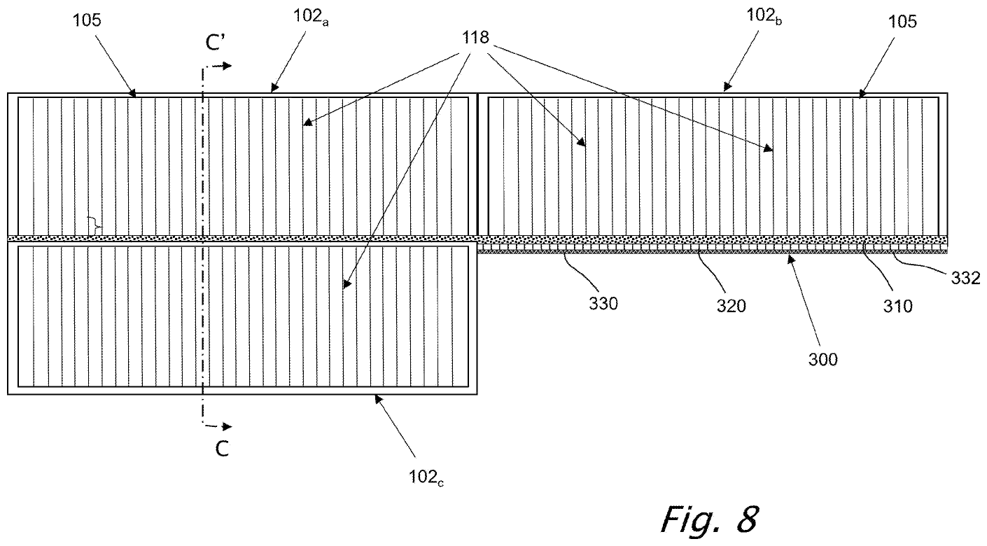

FIG. 6 illustrates an example side cross section view of PV solar cell 102 according to another embodiment of the present invention, similar to the PV solar cell shown in FIG. 2, wherein PV solar cell 102 is typically, with no limitations, made of silicon. However, in this embodiment, each row of m PV solar cells 102 is interconnected to the previous row of m PV solar cells 102, both in series and in parallel, by a long multi-layer, parallel and serial connection conductor foil (300, see FIG. 7a, below). PV solar cell 102 further include a conductive upper pad 131 proximal to the front end of upper conductive contact grid 130, and a conductive lower pad 133 proximal to the rear end of lower conductive contact grid 132.

A solar panel of the present invention further includes at least m−1 multi-layer, parallel and series conductor foils 300, one of which is illustrated by way of example in FIGS. 7a and 7b. Multi-layer, parallel and series connection conductor foil 300 has a width that facilitates connecting in series and in parallel at least n PV solar cells 102. Multi-layer, parallel and series connection conductor foil 300 is made of an upper non-conductive transparent polymer foil 310 with an adhesive lower side 312, a metal foil 320 that is solder ready coated, and a lower non-conductive polymer foil 330 with an adhesive upper side 332. The three layers are glued together in a staggering manner such that parts of the adhesive lower side 312 and the adhesive upper side 332 are left untouched.

Reference is also now made to FIG. 8, which is a top view of the first rows of two strings of PV solar cells 102 of the m strings and n rows of the array of m×n PV solar cell 102 that are electrically connected in series, wherein one PV solar cell is shown removed for illustrative purposes only.

In should be appreciated that the lamination process of the solar panels, that is going with temperature higher than melting temperature of solder, all cells will be soldered to the respective parallel and series connection conductor (200, 300).

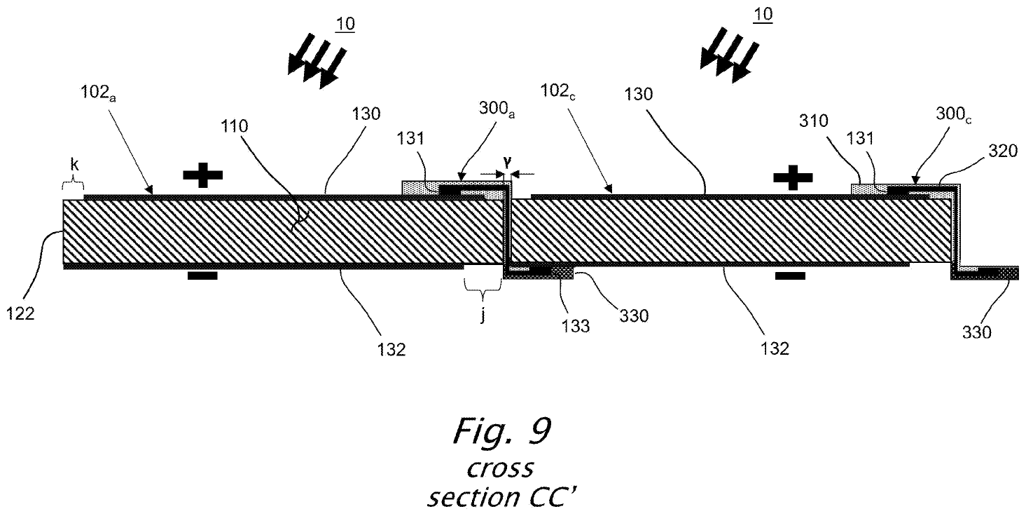

Reference is also made to FIG. 9, which is a side cross section view CC′ of the first two rows of PV solar cells 102 (of the m rows of PV solar cell 102) that are electrically connected in series. The electrically positive side conductor, upper conductive contact grid 130 of each PV solar cell 102 is connected in series with the electrically negative side, lower conductive contact grid 132 of the next solar cell 102 of the same string of solar cells. The gap between the two connected cells is y=0. Multi-layer, parallel and series connection conductor 300a is shown connecting the positive side conductor, upper conductive contact grid 130 of the first PV solar cells 102a with the negative side, lower conductive contact grid 132 of the next PV solar cell 102b of the same string of PV solar cells 102.

Referring back to FIG. 8, the upper non-conductive transparent polymer foil 310 (see FIG. 8) is placed over the edge of the first row of solar cell 102 (represented here, by way of example, by PV solar cells 102a and 102b) whereas metal foil 320 that is solder ready coated, makes contact with the electrically positive side conductor, upper conductive contact grid 130 of the of each PV solar cell 102, in particular, with the respective upper pads 131. Thereby, metal foil 320 collects the electric energy from the respective contact grid (fingers, busbars of contact pads are a part of contact grid) 105 of all n strings. Optionally, metal foil 320 can be extended for connection to buses (bus belt that provide connection to junction boxes) and/or bypass diodes.

Each multi-layer, parallel and series conductor foil 300 is configured to serially connect to the next stuck of m PV solar cells 102, as illustrated by way of example in FIG. 9. The lower non-conductive transparent polymer foil 330 (see FIG. 8) is placed under the edge of the next row of solar cell 102 (represented here, by way of example, by PV solar cells 102a and 102c) whereas metal foil 320 that is solder ready coated, makes contact with the electrically negative side, lower conductive contact grid 132 of the of each PV solar cell 102a, in particular, with the respective lower pads 133.

In the next step another m PV solar cells 102 are placed in stuck over the lower non-conductive transparent polymer foil 330 of multi-layer, parallel and serial conductor foils 300, This process proceeds until all of the m rows of PV solar cell 102 are in place. All layers of multi-layer, parallel and serial conductor foils 300 are conductively bonded on the respective PV solar cells 102 during the manufacturing process of the PV solar cells array.

Once the whole array of m×n PV solar cells (100 or 102) is assembled, the array of m×n PV solar cells is conveyed through an appropriate soldering oven. Optionally, when using a foil that coated with matter that melts in a low temperature, the melting step may be performed at the final lamination step. It should be appreciated that soldering the whole array in a single step constitute substantial manufacturing complexity and time, compare to conventional panels of PV solar cells that solders each string of the PV solar cells separately.

It should be appreciated that all PV solar cells may be regular PV solar cells or cut PV solar cells.

While example materials for elements have been described, the present disclosure invention is not limited by these materials.

Various modifications can be made in the design and operation of the present disclosure invention without departing from its spirit. Thus, while examples of construction of the present disclosure invention have been explained in what is now considered to represent its example embodiments, it should be understood that within the scope of the patent, the present disclosure invention may be practiced otherwise than as specifically illustrated and described.

The features disclosed in the above description and in the drawings may be significant both individually and in any desired combination in order to realize the various embodiments of the present disclosure.

Although the present disclosure invention has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by this patent.

While certain embodiments of the inventions have been described, wherein these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

The present invention being thus described in terms of several embodiments and examples, it will be appreciated that the same may be varied in many ways. Such variations are not to be regarded as a departure from the spirit and scope of the invention, and all such modifications as would be obvious to one skilled in the art are contemplated.

What is claimed is:

1. A method for manufacturing a PV solar cells matrix array (SCMA) of generally quadrangular solar cells (100, 102), having a rear side (122), a front side (120), an upper side covered by an upper conductive contact grid (130) having a first electric pole (FEP), and a lower side covered by a lower conductive contact grid (132) having a having a second electric pole (SEP) being opposite to said FEP, wherein each row of the SCMA includes m solar cells, and each column of the array of solar cells includes n solar cells, all of which are electrically interconnect both in series and in parallel, the method comprising the steps of:
a) providing n−1 flexible, parallel-and-serial connection conductors (200, 300), each comprising an upper horizontal surface (210), a generally vertical surface (220), and a bottom horizontal surface (230),
wherein said flexible, parallel-and-serial connection conductors are single layer parallel-and-serial connection conductors (200);
wherein said vertical surface of each of said single layer parallel-and-serial connection conductor is configured to be attached to either the front side, the rear side or both the front and rear sides, of each of said m placed solar cells;
wherein said upper horizontal surface of each said single layer parallel-and-serial connection conductors (200), except for the first row, is configured to be conductively attached to the respective upper conductive contact grid of the previous solar cell; and
wherein said bottom horizontal surface of each said single layer parallel-and-serial connection conductors, except for the last row, is configured to be conductively attached to the respective lower conductive contact grid of the next solar cell,
b) providing m×n PV solar cells;
c) assembling the array of m×n PV solar cells wherein,
proceeding with either:
i) placing a stuck row of m of said solar cells onto a flat surface,
placing said vertical surface of a single layer parallel-and-serial connection conductor adjacent to said front side of said placed stuck row of m of solar cells, and
wherein said upper horizontal surface (210) of said placed single layer parallel-and-serial connection conductor is placed adjacent to said upper conductive contact grid (130) of the said placed stuck row of m of said solar cells;
ii) placing the next stuck row of m of said solar cells onto a flat surface, wherein the rear end of said lower conductive contact grid (132) of said placed stuck row of m of said solar cells is placed over and adjacent to bottom horizontal surface (230);
iii) placing said vertical surface of said first single layer parallel-and-serial connection conductor adjacent to said front side of said placed stuck row of m of said solar cells;
iv) repeat steps vi-vii until reaching the last stuck row of m of said solar cells;
v) placing the n^{th} stuck row of m of said solar cells onto a flat surface, wherein the rear end of said lower conductive contact grid (132) of said last placed stuck row of m of said solar cells is placed over and adjacent to bottom horizontal surface (230),
or with:
i) providing a first single layer parallel-and-serial connection conductor;
ii) placing a stuck row of m of said solar cells onto a flat surface,
wherein said vertical surface of said provided single layer parallel-and-serial connection conductor is placed adjacent to said front side of said placed stuck row of m of said placed solar cells, and
wherein said lower horizontal surface of the last placed single layer parallel-and-serial connection conductor is placed adjacent said lower conductive contact grid (132) of the last placed stuck row of m of said solar cells, except for the last row;
iii) placing the next stuck row of m of said solar cells onto a flat surface, wherein the rear end of said upper conductive contact grid (130) of said placed stuck row of m of said solar cells is placed below and adjacent to upper horizontal surface (210);
iv) placing said vertical surface of said first single layer parallel-and-serial connection conductor adjacent to said front side of said placed stuck row of m of said solar cells;
v) repeat steps vi-vii until reaching the last stuck row of m of said solar cells;
placing the n^{th} stuck row of m of said solar cells onto a flat surface, wherein the front end of said upper conductive contact grid (130) of said placed stuck row of m of said solar cells is placed below and adjacent to upper horizontal surface (210),
d) soldering said assembled array of m×n PV solar cells.

2. The method for manufacturing a SCMA of claim 1, wherein said parallel-and-serial connection conductor (200) is made of conductive material.

3. The method for manufacturing a SCMA of claim 2, wherein said conductive material is cupper or silver.

4. The method for manufacturing a SCMA of claim 1, wherein said parallel-and-serial connection conductor is a multi-layer, parallel and serial conductor foil (300).

5. The method for manufacturing a SCMA of claim 4, wherein said multi-layer, parallel and serial conductor foil comprises:
a. an upper non-conductive polymer foil (310) with an adhesive lower side (312);
b. a metal foil (320) that is solder ready coated; and
c. a lower non-conductive polymer foil (330) with an adhesive upper side (332), wherein said three layers are glued together in a staggering manner such that parts of the adhesive lower side (312) and the adhesive upper side (332) are left untouched.

6. The method for manufacturing a SCMA of claim 5, wherein either said upper non-conductive polymer foil, said lower non-conductive polymer foil (330), or both are transparent.

7. The method for manufacturing a SCMA of claim 2, wherein said soldering of the assembled array of m×n PV solar cell is performed using low temperature soldering, or by using high temperature soldering, or a combination of both high temperature soldering and low temperature soldering.

8. The method for manufacturing a SCMA of claim 1, wherein said flat surface is a receptor conveyor.

9. The method for manufacturing a SCMA of claim 1, wherein said upper conductive contact grid (130) further includes a conductive pad, and wherein the respective parallel and serial conductor (200, 300) is configured to be conductively attached to said plus conductive pad.

10. The method for manufacturing a SCMA of claim 1, wherein said lower conductive contact grid (132) further includes a conductive pad, and wherein the respective parallel and serial conductor (200, 300) is configured to be conductively attached to said minus conductive pad.

11. The method for manufacturing a SCMA of claim 1, wherein a non-conductive region j is kept between the front end of said lower conductive contact grid (132) and the front side of the body of the respective PV solar cell.

12. The method for manufacturing a SCMA of claim 1, wherein a non-conductive region k is kept between the rear end of upper lower conductive contact grid (130) and the rear side of the body of the respective PV solar cell.

13. The method for manufacturing a SCMA of claim 1, wherein said PV solar cells are regular solar cells.

14. The method for manufacturing a SCMA of claim 1, wherein said PV solar cells are cut from regular solar cells.

15. The method for manufacturing a SCMA of claim 1, wherein said upper conductive contact grid (130) is configured to face the incoming light.
